(19) United States
(12) Patent Application Publication
(10) Pub. No.: US 2011/0017981 A1
(43) Pub. Date: Jan. 27, 2011

(54) PROCESS FOR THE PREPARATION OF SEMICONDUCTING LAYERS

(75) Inventors: Gordon Bradley, Liestal (CH); Lukas Burgi, Zurich (CH); Frank Bienewald, Hegenheim (FR)

Correspondence Address: BASF Corporation;Patent Department, 500 White Plains Road, P.O. Box 2005, Tarrytown, NY, 10591, US

(73) Assignee: BASF SE, Tarrytown, NY (US)

(21) Appl. No.: 12/745,075

(22) PCT Filed: Dec. 5, 2008
(86) PCT No.: PCT/EP08/66839

§ 371 Date: Sep. 17, 2010

(30) Foreign Application Priority Data
Dec. 14, 2007 (EP) 07123248.2

(51) Int. Cl. H01L 51/05; H01L 51/40; H01L 51/42

(52) U.S. Cl. 257/40; 438/99; 257/E51.003; 257/E51.012; 257/E51.024

(57) ABSTRACT

A convenient way for preparing thin layers of organic semiconducting materials comprises application or deposition of particles of a semiconducting material containing an organic semiconductor on a suitable surface, and converting these particles into a semiconducting layer on a substrate by application of pressure and optionally elevated temperatures.

The present invention pertains to a process for the preparation of semiconducting layers by pressure and optional temperature treatment, as well as to compositions and devices obtained by this process.

In order to replace more elaborate layer deposition techniques originating from the use of inorganic semiconductors, the preparation of organic semiconducting layers, especially for the large scale production of electronic devices, by coating techniques has been discussed. These techniques usually require application of a solution of the semiconducting material e.g. by spin-coating, ink-jet printing or other coating technologies.

In order to obtain an organic semiconductor thin film that manifests superior TFT characteristics, it is considered very important that a crystalline structure in which the molecules are arranged in a highly regular manner within the organic semiconductor film is present. However, since most organic semiconducting materials such as polyacene compounds are difficult to dissolve in organic solvents or do not dissolve at all, the processing, if feasible at all, commonly leads to low performance.

It has now been found that the quality of a semiconducting layer can be greatly improved, without the need to employ expensive deposition techniques such as vapour deposition, when separated particles of the semiconducting material are applied on a suitable surface, e.g. by coating the surface with a dispersion of the particles and an optional drying step, and these particles are subsequently converted into the desired layer on the substrate by means of a pressure and optional temperature treatment. A preferred process utilises high pressure and elevated temperatures to improve the crystalline morphology of organic semiconductor layers.

The invention thus pertains to a process for the preparation of an electronic device, which process comprises application or deposition of particles of a semiconducting material containing an organic semiconductor on a suitable surface, and converting these particles into a semiconducting layer on a substrate by application of pressure and optionally elevated temperatures.

In a further aspect, the invention pertains to a process for the preparation of an electronic device, which process comprises the formation of a semiconducting layer on a substrate by application of a semiconducting material containing an organic semiconductor on a suitable surface, and subjecting the semiconducting material to pressure in the range 12000 to 100000 kPa, especially 12000 to 50000 kPa, and optionally to elevated temperatures.

A preparation of an electronic device may comprise a step according to the invention wherein a semiconducting layer is formed on a substrate by application of a semiconducting material containing an organic semiconductor on a suitable surface, and subjecting the semiconducting material to dynamic or directional pressure and optionally to elevated temperatures.

Where semiconducting material other than in particle form is applied to the substrate, the material usually is applied to the form of a solid thin layer before being subjected to high pressure and elevated temperature.

In the process of the invention, semiconducting material applied comprises one or more organic semiconducting compounds, which optionally may be combined with one or more other further components or auxiliaries; examples are dispersants, high melting crystal growth promoters, plasticizers, mobility enhancers, dewetting agents, dopants, binders. Components of these classes are well known in the field of organic electronics, or in the fields of coating technology and/or plastics processing.

The optional dispersing agent serves to stabilize the dispersed semiconductor material against flocculation, aggregation or sedimentation and thereby maintains the dispersion in a finely divided state. Many types of dispersing agents are known including non-ionic (e.g., ethoxylated long-chain alcohols, glyceryl stearate and alkanolamides), anionic (e.g., sodium lauryl sulfate, alkylnaphthalene sulfonates and aliphatic-based phosphate esters), cationic (e.g., trimethy cetyl ammonium chloride, oleic imidazoline and ethoxylated fatty amines), and amphoteric (e.g., lecithin and polyglycol ether derivatives) surfactants and they can be monomers, oligomers or polymers.

Dewetting agents or further dispersants may often be selected from widely known tensides or surfactants of suitable properties (see also section on dispersions further below). Suitable solvents, especially those of high boiling points such as hydrocarbons, ketones or alcohols, e.g. of 7-18 carbon atoms, may often be used as crystal growth promoters.

Carbon nanotubes, fullerenes or related structures, e.g. forming organic semiconductor composites, are examples for useful mobility enhancers (Matsushita Electric, Samsung).

The binder can, in principle, be any binder which is customary in industry, for example those described in Ullmann's Encyclopedia of Industrial Chemistry, 5th Edition, Vol. A18, pp. 368-426, VCH, Weinheim 1991. In general, it is a film-forming binder based on a thermoplastic or thermosetting resin, predominantly on a thermosetting resin. Examples thereof are alkyd, acrylic, polyester, phenolic, melamine, epoxy and polyurethane resins and mixtures thereof. More specific examples of binder resins include oligomers and polymers such as poly(vinyl butyral), polyesters, polycarbonates, poly(vinyl chloride), polyacrylates and methacrylates, copolymers of vinyl chloride and vinyl acetate, phenoxy resins, polyurethanes, poly(vinyl alcohol), polyacrylonitrile, polystyrene, and the like.

In certain applications, the binder material may function as the dispersant, or may be used as dispersant in combination with a non-permanent solvent, for the semiconductor particles, especially in case of deposition of the particle dispersion at elevated temperatures (e.g. 40-150° C.).

Dopants: In organic semiconductors, dopants are not limited to a specific position and may diffuse freely inside the material. Such diffusion increases the electrical conductivity in the channel region. A number of publications (Infineon) tackles this diffusion problem by
a dopant irreversibly fixed in the organic semiconductor
embedding activated nanoparticles in the vicinity of the contact areas
applying a reactive intermediate layer which dopes the organic semiconductor layer region-selectively in the contact region.

Further dopants useful include organic oligomers comprising an acid functional group, which have been designed for application in the interfacial zone between the semiconductor material and the first electrically conductive region (Plastic Logic).

Other additives in the organic semiconductor layer include nanoparticles or nanowires, as proposed for use within a pentacene layer (IBM) to operate as electron carriers.

In case that elevated temperatures are applied, the organic semiconductor(s) often may become subjected to an initial pressure step and later to elevated temperatures, with or without the high pressure being maintained, or high pressure and elevated temperatures are applied simultaneously. Treatment of the compacted organic semiconductor layer with elevated temperatures, either still at high pressure or at normal pressure, allows the organic layer to anneal. This results in better semiconductor performance, especially in charge carrier mobility. Thus, an annealing step, e.g. for a time from 1 to 3000 s, may follow.

In certain industrial applications, a process may be advantageous wherein the pressure treatment follows the heat application step.

Before being subjected to high pressure and optionally elevated temperature, the organic semiconductor particles often are in the form of a powder, dispersed powder and/or pellets. Particles of the semiconducting material are usually from the size range 5-5000 nm, especially 10-1000 nm. The particles may be in the form of aggregates, homogenous single particles, or mixtures thereof. Aggregates usually are dimensioned more in the upper range, e.g. 300-3000 nm, while the dimensions of homogenous particles, or even single crystals, usually are more in the lower range of dimensions such as 10-500 nm.

In one way of carrying out the present invention, the semiconducting material is applied as a powder or a particle dispersion in a volatile liquid, especially an organic liquid boiling at normal pressure within the range 30-200° C. or water or mixtures of the organic liquid with water. The dispersion liquid may comprise a further component in dispersed or preferably dissolved form, such as a surfactant or dispersing agent. Layer deposition may be effected by known methods including spin coating, blade coating, rod coating, screen printing, ink jet printing, stamping etc. The particles may be applied directly to the substrate surface or to the surface of a stamping or printing tool.

A high-speed “printing” process utilising the current invention can be envisaged as follows:
A homogeneous dispersion of organic semiconductor is printed using a classical printing process;
high pressure (possibly also at elevated temperature) is applied to the organic semiconductor print for a short duration of time to compact the print, and
the compacted print is “after-annealed” at elevated temperature using a long heating tunnel (e.g. containing infra-red heaters).

The pressure applied advantageously is in the range of 120 to 100000 kPa, preferably in the range of 150 to 50000 kPa. Pressure is usually applied in the form of dynamic pressure. The time period for the application of pressure often is chosen from the range 0.01 to 3000 s.

Elevated temperatures, if applied, are often chosen from the range from above room temperature to about 300° C., e.g. 40 to 250° C., depending on the material to be used. An annealing temperature may be chosen from the same range, often from about 50-200° C.

The semiconductor employed is usually selected from organic semiconducting compounds. Particles of inorganic semiconductors may be admixed; if present, these compounds are advantageously contained in an amount up to 5% b.w. of the total semiconducting material employed (in the form of particles or, after the pressure treatment according to the invention, as compressed particles or layers). The semiconducting material, especially the particles thereof, may contain one single organic semiconductor or more than one organic semi-conductor. The organic semiconductor usually makes up 60 to 100% b.w. of the particle material, often at least 90% b.w. of the particle material. Particle materials of specific industrial interest are those consisting essentially (e.g. by 90% b.w. or more) of one organic semiconducting compound. Organic semiconductors may be chosen from low molecular weight compounds, especially from the range 180-2000 g/mol such as 180-800 g/mol, or high molecular weight compounds, such as polymers, especially from the molecular weight range 1000-300000 g/mol. The semiconducting material may comprise a mixture of organic semiconductors, e.g. a mixture of a low molecular weight compound and a polymeric species.

The semiconducting layer obtained in the process of the invention usually has a thickness of less than 10000 nm. Depending on the intended use and materials chosen, the thickness may, for example, be within the range 10-300 nm, or within the range 100-1000 nm. Preferably the thickness of the organic semiconductor layer is in the range of from about 5 to about 200 nm.

### Semiconductors

Suitable materials for the semiconductor material include n-type semiconductor materials (where conductivity is controlled by negative charge carriers) and p-type semiconductor materials (where conductivity is controlled by positive charge carriers).

### Chemical Classes

### A. Low Molecular Compounds

Polyconjugated organic compounds containing at least 8 conjugated bonds and have a molecular weight of no greater than approximately 2,000

p-Type
acenes including anthracene, naphthalene, tetracene, pentacene, and pentacene derivatives
quinoid diheteroacenes
phthalocyanines (U.S. Pat. No. 6,150,191: Lucent)
substituted indolcarbazoles (US 20060124921, Xerox)
compounds having a porphyrin skeleton
bis-(2-acenyl) acetylenes (U.S. Pat. No. 7,109,519: 3M)
acene-thiophene (U.S. Pat. No. 6,998,068: 3M)
cyanine dyes
alpha, alpha′-bis-4(n-hexyl)phenyl bitiophene
thienothiophene derivatives (U.S. Pat. No. 6,818,260: Merck)
   n-Type
Aromatic tetracarboxylic diimides, such as N,N′-diaryl naphthalene-1,4,5,8-bis(dicarboximide) compounds (U.S. Pat. No. 6,861,664: Xerox)
perylene tetracarboxylic acid diimide compounds (U.S. Pat. No. 7,026,643: IBM)
perfluorinated copper phthalocyanine
tetracyanonaphthoquino-dimethane (TCNNQD)
dioxaborines (US 20030234396: Infineon)

### B. Conjugated Polymers

p-Type
polyacetylene derivatives,
polythiophene derivatives having a thiophene ring (US 006051779: Samsung)
poly(3-alkylthiophene) derivatives,
poly(3,4-ethylenedioxythiophene) derivatives,
polythienylene-vinylene derivatives,
polyphenylene derivatives having a benzene ring,
polyphenylenevinylene derivatives,
polypyridine derivatives having a nitrogen atom,
polypyrrole derivatives,
polyaniline derivatives,
polyquinoline derivatives
oligomers such as dimethylsexithiophene, and quaterthiophene;
   n-Type
alpha,omega-diperfluorohexylsexithiophene (U.S. Pat. No. 6,608,323 Northwestern University)
fluorinated polythiophenes (U.S. Pat. No. 6,960,643: Xerox U.S. Pat. No. 6,676,857: Merck)
perfluoroether acyl oligothiophene compounds (U.S. Pat. No. 7,211,679: 3M)

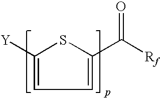

### C. Liquid Crystalline Organic Semiconductor Materials

alkyl group, or acetylene skeletons introduced symmetrically into said thiophene skeleton. (US20070045613: Dai Nippon Printing)

### D. Self-Organizable Polymers

e.g. U.S. Pat. No. 7,005,672, Xerox

### E. Organic Semiconductor Precursors

U.S. Pat. No. 6,963,080: IBM
US 2006166409: Philips

### F. Inorganic Semiconductors

may be selected from known components, especially the known forms of silicon (preferably amorphous), e.g. in the form of silicon particles or clusters, which may be dispersed within the organic semiconductor layer to improve the electrical properties.

Organic semiconducting compounds for use in the present invention are usually selected from those capable of film forming (preferably in form of a highly homogenous layer). The present organic semiconducting compounds may be selected from polycyclic aromatic hydrocarbons; heterocyclic analogues thereof such as corresponding aza-compounds; corresponding quinoid systems especially comprising aza- and/or oxa-analogues of corresponding hydrocarbons; substituted derivatives of any thereof such as variants substituted by halogen such as fluoro, hydroxy, alkoxy, aryloxy, cyano, diarylamino, arylalkylamino, dialkylamino, trialkylsilyl, triarylsilyl, dialkylarylsilyl, diarylalkylsilyl, keto, dicyanomethyl, C₁-C₂₄alkyl, C₂-C₂₄alkenyl, C₂-C₂₄alkynyl, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent substituents form an annelated benzo-, naphtho-, anthra-, phenanthro-, fluorantheno-, pyreno-, triphenyleno-, or peryleno-substituent or its alkyl or aryl substituted derivative; or any two substituents form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, ace, or indeno substituent or their alkyl or aryl substituted derivative; which compounds are well known in the art; examples being listed inter alia in US 2004/0076853 sections [0168] to [1382], [1385] to [1475], [1498] to [1513], [1522] to [1629], the corresponding sections being hereby incorporated by reference.

Semiconducting compounds of more specific interest include those of WO06/120143, especially as defined on page 3 (formula I) and pages 7-8 (structures II and III):

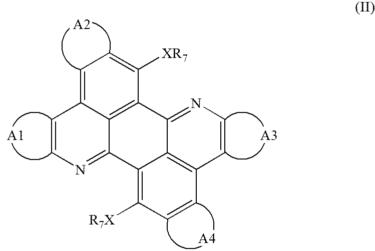

wherein

A1, A2, A3 and A4 each independently are bridge members completing, together with the carbon atoms they are bonding to, an unsubstituted or substituted aromatic carbocyclic 6-membered ring or N- and/or S-heterocyclic 5-membered ring,

R7 independently is H or unsubstituted or substituted alkyl, unsubstituted or substituted alkenyl, unsubstituted or substituted alkynyl, unsubstituted or substituted aryl, and

X is O, S, NR8;

R8 is H, C₁-C₁₂alkyl or C₃-C₁₂alkenyl which is unsubstituted or substituted by halogen or OH or NR10R10,

where R10 is H, C₁-C₁₂alkyl, C₄-C₁₂cycloalkyl.

In preferred compounds of the formula II, R7 is as defined above for preferred compounds of the formula I; X is most preferably O;

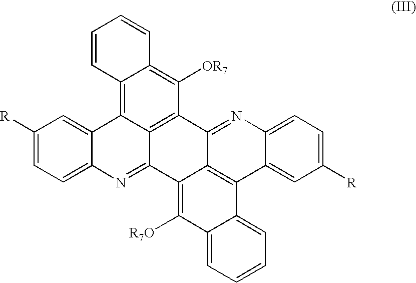

wherein

R independently is H, halogen, OH, unsubstituted or substituted alkyl, unsubstituted or substituted alkoxy, unsubstituted or substituted alkylthio, unsubstituted or substituted aryl, and

R7 independently is H, alkyl, alkenyl or alkynyl, especially alkyl;

WO07/068,618, especially of the formulae

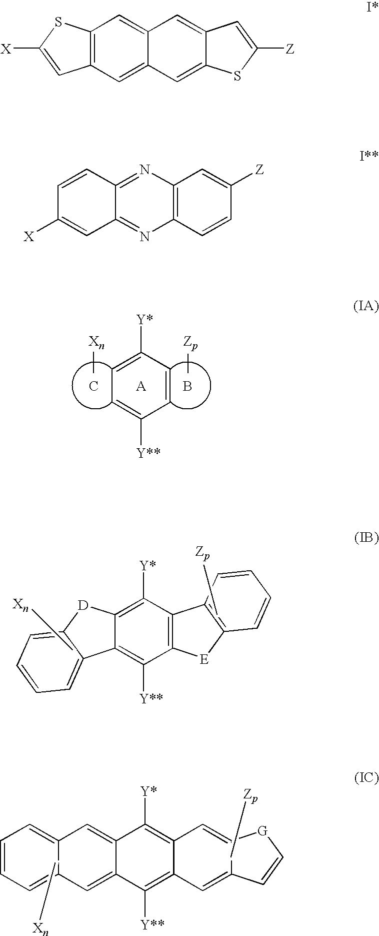

wherein

the ring marked B is a mono- or polycyclic, preferably mono-, di- or tricyclic unsaturated ring or ring system or ferrocenobenzo of the subformula I(i)

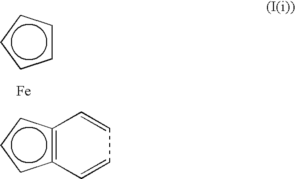

wherein the dotted bond marks the side of the benzo ring annealed to the central ring A in formula I, each annealed to ring A and the ring marked C is a mono- or polycyclic, preferably mono-, di- or tricyclic unsaturated ring or ring system or ferrocenobenzo of the subformula I(i) shown above, each annealed to ring A, each of rings or ring systems B and C may also carry a group ═S, ═O or ═C(NQ₂)₂ (the binding double bond of which is in conjugation with the ring double bonds), where in each case where mentioned “unsaturated” means having the maximum possible number of conjugated double bonds, and wherein in at least one of rings or ring systems B and C at least one ring atom is a heteroatom selected from P, Se or preferably N, NQ, O and S, if each first ring (forming or forming part of ring or ring system B and C) directly annealed to ring A has six ring atoms;

Q is independently selected from hydrogen and (preferably) unsubstituted or substituted hydrocarbyl, unsubstituted or substituted hydrocarbylcarbonyl and unsubstituted or substituted heteroaryl;

not more than two of the substitutents X, Y and Z are substituted ethynyl, wherein the substitutents are selected from the group consisting of unsubstituted or substituted hydrocarbyl with up to 40 carbon atoms, unsubstituted or substituted hydrocarbyloxy with up to 40 carbon atoms, hydrocarbylthio with up to 40 carbon atoms, unsubstituted or substituted heteroaryl, unsubstituted or substituted heteroaryloxy, unsubstituted or substituted heteroarylthio, cyano, carbamoyl, wherein Hal represents a halogen atom, substituted amino, halo-C₁-C₈-alkyl, such as trifluoromethyl, halo, and substituted silyl;

while the remaining X, Y and/or Z are selected from the group consisting of hydrogen, unsubstituted or substituted C₁-C₂₀-alkyl, such as halo-C₁-C₂₀-alkyl, unsubstituted or substituted C₂-C₂₀-alkenyl, unsubstituted or substituted C₂-C₂₀-alkynyl, unsubstituted or substituted C₆-C₁₄-aryl, especially phenyl or naphthyl, unsubstituted or substituted heteroaryl with 5 to 14 ring atoms, unsubstituted or substituted C₆-C₁₄-aryl-C₁-C₂₀-alkyl, especially phenyl- or naphthyl-C₁-C₂₀-alkyl, such as benzyl, unsubstituted or substituted heteroaryl-C₁-C₂₀-alkyl, wherein the heteroaryl has 5 to 14 ring atoms, unsubstituted or substituted ferrocenyl, unsubstituted or substituted C₁-C₂₀-alkanoyl, such as unsubstituted or perfluorinated C₂-C₁₂-alkanoyl, halo, unsubstituted or substituted C₁-C₂₀-alkoxy, C₂-C₂₀-alkenyloxy, C₂-C₂₀-alkynyloxy, unsubstituted or substituted C₁-C₂₀-alkylthio, C₂-C₂₀-alkenylthio, C₂-C₂₀-alkynylthio, carboxy, unsubstituted or substituted C₁-C₂₀-alkoxy-carbonyl, unsubstituted or substituted phenyl-C₁-C₂₀-alkoxy-carbonyl, amino, N-mono- or N,N-di-(C₁-C₂₀-alkyl, C₁-C₂₀-alkanoyl and/or phenyl-C₁-C₂₀-alkyl)amino, cyano, carbamoyl, N-mono- or N,N-di-(C₁-C₂₀-alkyl, C₁-C₂₀-alkanoyl and/or phenyl-C₁-C₂₀-alkyl)carbamoyl and sulfamoyl, and each of n and p is 0 to 4;

Y* and Y** are independently selected from substituted ethynyl as defined above;

each of D, E and G is a heteroatom independently selected from the group consisting of O, NQ or S;

quinoid semiconductors of WO07/118,799, such as those of the formula

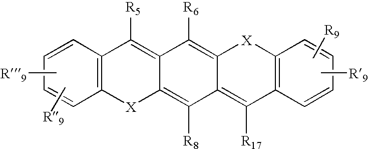

wherein

X stands for O, S or NR′,

R′ is selected from unsubstituted or substituted C₁-C₁₈alkyl, unsubstituted or substituted C₂-C₁₈alkenyl, unsubstituted or substituted C₂-C₁₈alkynyl, unsubstituted or substituted C₄-C₁₈aryl;

each of R₅, R₆, R₁₇, R₈ independently is selected from H; unsubstituted or substituted C₁-C₂₂alkyl or C₂-C₂₂alkenyl, each of which may be interrupted by O, S, COO, OCNR10, OCOO, OCONR10, NR10CNR10, or NR10; substituted C₂-C₁₈alkynyl; unsubstituted or substituted C₄-C₁₈aryl; halogen; silylXR₁₂;

R₉, R′₉, R″₉, R′″₉ independently are as defined for R₅, or adjacent R₉ and R′₉ and/or adjacent R″₉ and R′″₉, or R₅ and R′″₉, and/or R₇ and R′₉, together form an annealed ring;

R10 is H, C₁-C₁₂alkyl, C₄-C₁₂cycloalkyl;

each silyl is SiH(R11)₂ or Si(R11)₃ with R11 being C₁-C₂₀-alkyl or -alkoxy;

R₁₂ is silyl, acyl, unsubstituted or substituted C₁-C₂₂alkyl, unsubstituted or substituted C₄-C₁₈aryl;

each aryl is selected from C₄-C₁₈ aromatic moieties, which may contain, as part of the ring structure, one or 2 heteroatoms selected from O, N and S, preferred aryl are selected from phenyl, naphthyl, pyridyl, tetrahydronaphthyl, furyl, thienyl, pyrryl, chinolyl, isochinolyl, anthrachinyl, anthracyl, phenanthryl, pyrenyl, benzothiazolyl, benzoisothiazolyl, benzothienyl;

annealed rings, where present, are aromatic carbocyclic or N-heterocyclic, substituted or unsubstituted 6-membered rings; and

substituents, where present, bond to a carbon atom and are selected from C₁-C₂₂alkoxy, C₁-C₂₂alkyl, C₄-C₁₂cycloalkoxy, C₄-C₁₂cycloalkyl, OH, halogen, phenyl, naphthyl; while saturated carbons also may be substituted by oxo (═O); 2 adjacent substituents may be linked together, e.g. to form a lactone, anhydride, imide or carbocyclic ring, where preferred compounds conform to the structures

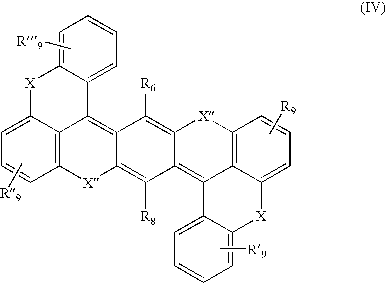

wherein

X′ stands for S or NR,

X and X″ stand for O, S or NR,

and all other symbols and preferred meanings are as defined above, an example being the structure

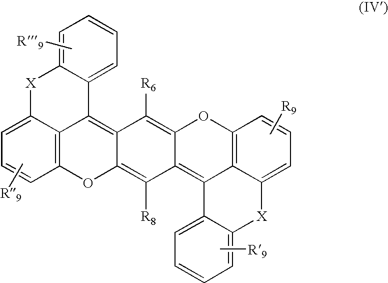

Examples for polymeric compounds include polythiophenes or polymers containing repeating units of the above compounds, especially those comprising a conjugated system throughout large sections of the polymer, or even consisting of the above compounds (formally formed by abstraction of 2 hydrogen atoms on such a compound, and replacing these hydrogen atoms with bonds to the next repeating unit).

Alkyl stands for any acyclic saturated monovalent hydrocarbyl group; alkenyl denotes such a group but containing at least one carbon-carbon double bond (such as in allyl); similarly, alkynyl denotes such a group but containing at least one carbon-carbon triple bond (such as in propargyl). In case that an alkenyl or alkynyl group contains more than one double bond, these bonds usually are not cumulated, but may be arranged in an alternating order, such as in —[CH═CH—]ₙ or —[CH═C(CH₃)—]ₙ, where n may be, for example, from the range 2-50. Preferred alkyl contains 1-22 carbon atoms; preferred alkenyl and alkinyl each contains 2-22 carbon atoms, especially 3-22 carbon atoms.

Any alkyl moiety of more than one, especially more than 2 carbon atoms, or such alkyl or alkylene moieties which are part of another moiety, may be interrupted by a heterofunction such as O, S, COO, OCNR10, OCOO, OCONR10, NR10CNR10, or NR10, where R10 is H, C₁-C₁₂alkyl, C₃-C₁₂cycloalkyl, phenyl. They can be interrupted by one or more of these spacer groups, one group in each case being inserted, in general, into one carbon-carbon bond, with hetero-hetero bonds, for example O—O, S—S, NH—NH, etc., not occurring; if the interrupted alkyl is additionally substituted, the substituents are generally not α to the heteroatom. If two or more interrupting groups of the type —O—, —NR10-, —S— occur in one radical, they often are identical.

The term alkyl, wherever used, thus mainly embraces especially uninterrupted and, where appropriate, substituted C₁-C₂₂alkyl such as methyl, ethyl, propyl, isopropyl, n-butyl, sec-butyl, isobutyl, tert-butyl, 2-ethylbutyl, n-pentyl, isopentyl, 1-methylpentyl, 1,3-dimethylbutyl, n-hexyl, 1-methylhexyl, n-heptyl, isoheptyl, 1,1,3,3-tetramethylbutyl, 1-methylheptyl, 3-methylheptyl, n-octyl, 2-ethylhexyl, 1,1,3-trimethylhexyl, 1,1,3,3-tetramethylpentyl, nonyl, decyl, undecyl, 1-methylundecyl, dodecyl, 1,1,3,3,5,5-hexamethylhexyl, tridecyl, tetradecyl, pentadecyl, hexadecyl, heptadecyl, octadecyl. Alkoxy is alkyl-O—; alkylthio is alkyl-S—.

The term alkenyl, wherever used, thus mainly embraces especially uninterrupted and, where appropriate, substituted C₂-C₂₂alkyl such as vinyl, allyl, etc.

Where aryl (e.g. in C₁-C₁₄-aryl) is used, this preferably comprises monocyclic rings or polycyclic ring systems with the highest possible number of double bonds, such as preferably phenyl, naphthyl, anthrachinyl, anthracenyl or fluorenyl. The term aryl mainly embraces C₁-C₁₈aromatic moieties, which may be heterocyclic rings (also denoted as heteroaryl) containing, as part of the ring structure, one or more heteroatoms mainly selected from O, N and S; hydrocarbon aryl examples mainly are C₆-C₁₈ including phenyl, naphthyl, anthrachinyl, anthracenyl, fluorenyl; examples for heterocyclics (C₁-C₁₈) include those of the following table:

| ring structure | name | monovalent residue |
|---|---|---|
| 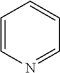 | pyridine | pyridyl |
| 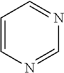 | pyrimidine | pyrimidyl |
| 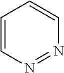 | pyridazine | pyridazyl |
| 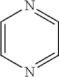 | pyrazine | pyrazyl |
| 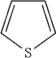 | thiophene | thienyl |
| 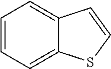 | benzothiophene | benzothienyl |
| 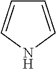 | pyrrol | pyrryl |
| 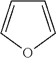 | furane | furyl |
| 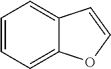 | benzofurane | benzofuryl, |
| 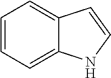 | indole | indyl |
| 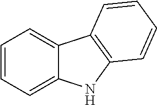 | carbazole | carbazolyl |
| 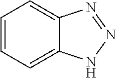 | benzotriazole | benzotriazolyl |
| 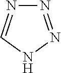 | tetrazole | tetrazolyl |
| 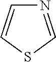 | thiazole | thiazolyl |
| 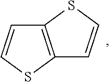 | | thienothienyl |
| 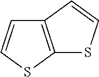 | | |
| 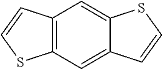 | | dithiaindacenyl |
| 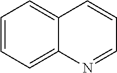 | | chinolyl |
| 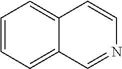 | | isochinolyl |
| 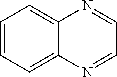 | | chinoxalyl |
| 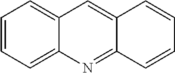 | | acridyl |

as well as azanaphthyl, phenanthryl, triazinyl, tetrahydronaphthyl, thienyl, pyrazolyl, imidazolyl,

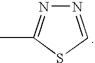

Preferred are C₄-C₁₈aryl, e.g. selected from phenyl, naphthyl, pyridyl, tetrahydronaphthyl, furyl, thienyl, pyrryl, chinolyl, isochinolyl, anthrachinyl, anthracenyl, phenanthryl, pyrenyl, benzothiazolyl, benzoisothiazolyl, benzothienyl; most preferred is phenyl, naphthyl, thienyl.

Acyl stands for an aliphatic or aromatic residue of an organic acid —CO—R′, usually of 1 to 30 carbon atoms, wherein R′ embraces aryl, alkyl, alkenyl, alkynyl, cycloalkyl, each of which may be substituted or unsubstituted and/or interrupted as described elsewhere inter alia for alkyl residues, or R′ may be H (i.e. COR′ being formyl). Preferences consequently are as described for aryl, alkyl etc.; more preferred acyl residues are substituted or unsubstituted benzoyl, substituted or unsubstituted C₁-C₁₇alkanoyl or alkenoyl such as acetyl or propionyl or butanoyl or pentanoyl or hexanoyl, substituted or unsubstituted C₅-C₁₂cycloalkylcarbonyl such as cyclohexylcarbonyl.

Halogen denotes I, Br, Cl, F, preferably Cl, F, especially F. Also of specific technical interest are perhalogenated residues such as perfluoroalkyl, e.g. of 1 to 12 carbon atoms such as CF₃.

Substituted silyl is preferably Si substituted by two or preferably three moieties selected from unsubstituted or substituted hydrocarbyl or hydrocarbyloxy (wherein the substituents are preferably other than substituted silyl), as defined above, or by unsubstituted or substituted heteroaryl. In case that Si carries only two substituents, the silyl group is of the type —SiH(R₂) with R₂ preferably being hydrocarbyl or hydrocarbyloxy. More preferred are three C₁-C₂₀-alkyl or -alkoxy substituents, i.e. substituted silyl then is Si(R11)₃ with R11 being C₁-C₂₀-alkyl or -alkoxy, especially three C₁-C₈-alkyl substitutents, such as methyl, ethyl, isopropyl, t-butyl or isobutyl.

In each case where mentioned, “unsaturated” preferably means having the maximum possible number of conjugated double bonds.

Preferred alkynyl residues are substituted ethynyl, i.e. ethynyl (—C≡C—H) wherein the hydrogen is substituted by one of the substitutents mentioned above, where general expression can preferably be replaced by the more detailed definitions given below.

Cycloalkyl such as C₃-C₁₂cycloalkyl includes cyclopropyl, cyclobutyl, cyclopentyl, cyclohexyl, cycloheptyl, cyclooctyl, cyclononyl, cyclodecyl, cycloundecyl, cyclododecyl; preferred among these residues are C₃-C₆cycloalkyl as well as cyclododecyl, especially cyclohexyl.

As substituted ethynyl, ethynyl substituted by unsubstituted or substituted C₁-C₂₀-alkyl (which can be primary, secondary or tertiary), unsubstituted or substituted phenyl, unsubstituted or substituted (e.g. 1- or 2-) naphthyl, unsubstituted or substituted (e.g. 1-, 2- or 9-) anthracenyl, an unsubstituted or substituted heteraryl moiety or a substituted silyl moiety selected from those given in the following table—the respective moiety can be bound via any ring atom appropriate, preferably by one of those marked with an asterisk, to the ethynyl moiety instead of a hydrogen in unsubstituted ethynyl—are especially preferred:

Table of some preferred substitutents for substituted ethynyl (which can be substituted or preferably unsubstituted as described above):

| | |
|---|---|
| 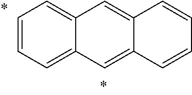 | 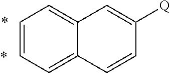 |
| 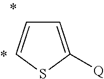 | 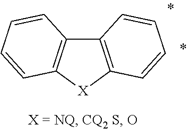 |
| 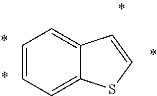 | 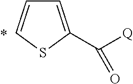 |
| 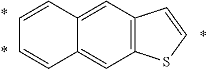 | 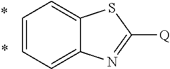 |
| 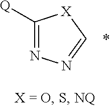 | 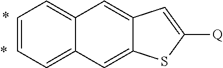 |
| 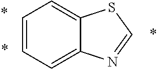 | 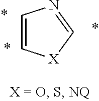 |
| 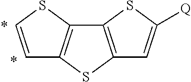 | 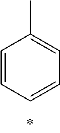 |
| 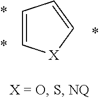 | 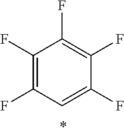 |
| 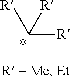 | 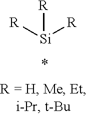 |
| 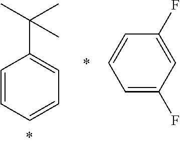 | 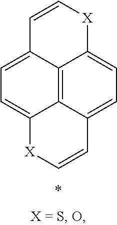 |
| 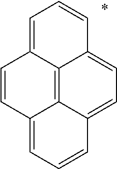 | 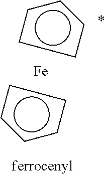 |
| 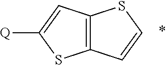 | 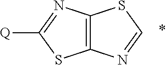 |
| 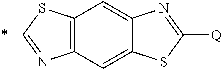 | 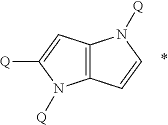 |
| 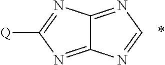 | 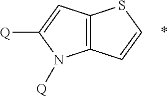 |
| 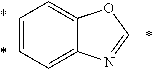 | 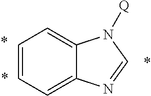 |

In the table, Q is as defined above for a compound of the formula I, especially selected from hydrogen, aryl, especially C₆-C₁₄-aryl, aryl-alkyl, especially phenyl- or naphthyl-C₁-C₂₀-alkyl, heteroaryl, especially with up to 14 ring atoms, and alkyl, especially C₁-C₂₀-alkyl.

### Particle Dispersions

The semiconducting materials may be converted into particles according to methods well known in the art, especially in the field of pigment technology, e.g. by particle surface treatment and/or addition of dispersants. A dispersion can be prepared by mixing and/or milling the organic semiconductor(s) and other components in the formulation in equipment such as paint shakers, ball mills, sand mills and attritors. Common grinding media such as glass beads, steel balls or ceramic beads may be used in such equipment.

Examples of solvents include ketones, alcohols, esters, ethers, aromatic hydrocarbons, halogenated aliphatic and aromatic hydrocarbons and the like and mixtures thereof. The particles may be pre-treated, e.g. for better dispersability, as similarly known in pigment technology. Organic semiconductor particles can utilise the know-how developed for dispersing pigments in water and organic solvents. Common methods include those wherein fine particles are dispersed into a liquid medium, where it is desirable for the particles to be dispersed as finely as possible and as rapidly as possible into the liquid medium and remain as a stable fine dispersion over time for optimum results. Since the dispersion of fine particles in a liquid often is unstable in that the particles tend to agglomerate or flocculate causing uneven distribution on the substrate. To minimize the effects of agglomeration or flocculation, the particles may be surface treated e.g. in analogy to methods described in

U.S. Pat. No. 6,878,799 (acid functional polymer dispersants)

U.S. Pat. No. 6,918,958 (acid dispersants and particle preparations)

U.S. Pat. No. 6,849,679 (compositions with modified block copolymer dispersants)

Depending on the type and polarity of the dispersing agent (e.g. water, organic solvents or mixtures thereof), polymers of variable structure are chosen. In view of ecological requirements, the use of aqueous dispersions is particularly preferred, as well as dispersions based on organic solvents with high solids content.

In aqueous systems, mixtures of hydrophobic and hydrophilic polymers or block copolymers, so-called A-B block copolymers, containing hydrophilic and hydrophobic polymer blocks are present. The hydrophobic “A” blocks (homo- or copolymers of methacrylate monomers) associate with either pigment or emulsion polymer surfaces or both. With hydrophilic “B” blocks (neutralised acid or amine containing polymers), these copolymers are useful for preparing water based pigment dispersions,

U.S. Pat. No. 6,736,892 (dispersions containing styrenated and sulfated phenol alkoxylates)

U.S. Pat. No. 6,689,731 (phosphoric esters as emulsifiers and dispersants)

U.S. Pat. No. 6,509,409 (polyurethane dispersants)

U.S. Pat. No. 6,506,899 (dispersants formed by reacting an isocyanate with a poly (ethylene glycol) alkyl ether, a polyester or polyester or polyacrylate and a diamine)

U.S. Pat. No. 6,852,156 (self-dispersing particles and process of making and use of same)

U.S. Pat. No. 6,410,619: Method for conditioning organic pigments

A suitable dispersion of a semiconducting particle for use in the present process thus may be obtained, for example, by

(a) milling a mixture comprising:

(1) one or more crude semiconductors, especially organic semiconducting compounds;

(2) at least about 0.1% by weight, relative to (1), of one or more acrylic copolymer dispersants; and

(3) 0 to about 100 parts by weight, relative to (1), of a milling liquid in which the semiconductor is substantially insoluble; and

(b) isolating the milled semiconductor material.

Acrylic copolymers may be used to disperse and maintain the semiconductor particles in a dispersed state, in analogy to conditioned organic pigments in coatings and other materials as described in U.S. Pat. Nos. 5,859,113 and 5,219,945, as well as U.S. Pat. Nos. 4,293,475, 4,597,794, 4,734,137, 5,530,043, and 5,629,367.

Generally, binders and/or dopants or the like may be present in a semiconductor device according to the present invention, however, preferably in an amount of less than 5%, e.g. in thin films in thin film transistors which are described in more detail below. Possible binders are, e.g., described in WO 2005/055248 which is incorporated here by reference.

### Semiconductor Devices

The method described in the invention can be used for the preparation of a semiconductor layer in semiconductor devices. There are numerous types of semiconductor devices. Common to all is the presence of one or more semiconductor materials. Semiconductor devices have been described, for example, by S. M. Sze in Physics of Semiconductor Devices, 2.nd edition, John Wiley and Sons, New York (1981). Such devices include rectifiers, transistors (of which there are many types, including p-n-p, n-p-n, and thin-film transistors), light emitting semiconductor devices (for example, organic light emitting diodes), photoconductors, current limiters, thermistors, p-n junctions, field-effect diodes, Schottky diodes, and so forth. In each semiconductor device, the semiconductor material is combined with one or more metals or insulators to form the device. Semiconductor devices can be prepared or manufactured by known methods such as, for example, those described by Peter Van Zant in Microchip Fabrication, Fourth Edition, McGraw-Hill, New York (2000).

A particularly useful type of transistor device, the thin-film transistor (TFT), generally includes a gate electrode, a gate dielectric on the gate electrode, a source electrode and a drain electrode adjacent to the gate dielectric, and a semiconductor layer adjacent to the gate dielectric and adjacent to the source and drain electrodes (see, for example, S. M. Sze, Physics of Semiconductor Devices, 2.sup.nd edition, John Wiley and Sons, page 492, New York (1981)). These components can be assembled in a variety of configurations. More specifically, an organic thin-film transistor (OTFT) has an organic semiconductor layer. FIG. 2 shows 2 common organic transistor designs.

Organic Schottky Diodes: Such a semiconductor diode has low forward voltage drop and a very fast switching action. Typical applications include discharge-protection for solar cells connected to lead-acid batteries and in switch mode power supplies; in both cases the low forward voltage leads to increased efficiency

The most evident limitations of Schottky diodes are the relatively low reverse voltage rating, 50 V and below, and a relatively high reverse current. The reverse leakage current, increasing with temperature, leads to a thermal instability issue. FIG. 8 gives a schematic view of an organic Schottky diode:

Substrate=12

Ohmic Contact=14

Doped buffer layer=16

Organic semiconductor layer=18

Schottky contact=20

Organic Solar Cells: Devices are based on an organic heterojunction which has the following functions:
Absorption of light
Exciton diffusion
Charge transfer
Charge collection

FIG. 9 gives a schematic view of an organic solar cellSchottky diode; OS=organic semiconductor.

The performance, and specifically the carrier mobility, of semiconductor devices containing organic functional material such as organic TFTs depends highly on the structural order of the organic film, which is determined both by its process of formation and by subsequent processing steps.

Organic semiconductors composed of “perfect” single crystals yield the highest transport mobilities in transistor applications. Single crystals, however, are difficult and costly to produce thus severely limiting their technological exploitation.

F. Schreiber describes in Physics of Organic Semiconductors (Chapter 2, Ed. by W. Brütting; Wiley-VCH) the various parameters which dictate the performance of an organic semiconductor within a thin film, including:

1. The definition of interfaces (degree of interdiffusion and roughness)

(a) organic-organic (e.g. in organic diodes)

(b) organic-metal (e.g. for electrical contacts)

(c) organic-insulator (e.g. in transistors (insulating layer between gate and semiconductor)

2. The crystal structure of the organic semiconductor

(a) type of structure/polymorphic form

(b) potential presence of co-existing structures

(c) orientation of the structure (epitaxy)

(d) is the structure strained? (epitaxy)

3. Crystalline quality/defect structure of the organic semiconductor layer

(a) Mosaicity (distinction between quality in the xy plane and in the z direction/surface normal)

(b) homogeneity within a given film (density of domain boundaries etc,)

(c) density of defects (and their nature) which impacts the electronic properties.

### Substrates

Typically, a substrate supports the OTFT during manufacturing, testing, and/or use. Optionally, the substrate can provide an electrical function for the OTFT. Useful substrate materials include organic and inorganic materials. For example, the substrate may comprise inorganic glasses, quartz, ceramic foils, undoped or doped silicon, polymeric materials (for example, acrylics, epoxies, polyamides, polycarbonates, polyimides, polyketones, poly(oxy-1,4-phenyleneoxy-1,4-phenylenecarbonyl-1,4-phenylene) (sometimes referred to as poly(ether ether ketone) or PEEK), polynorbornenes, polyphenyleneoxides, poly(ethylene naphthalenedicarboxylate) (PEN), poly(ethylene terephthalate) (PET), poly(phenylene sulfide) (PPS)), filled polymeric materials (for example, fiber-reinforced plastics (FRP)), and coated metallic foils.

A flexible substrate is preferred in some embodiments of the present invention. This allows for roll processing, which may be continuous, providing economy of scale and economy of manufacturing over some flat and/or rigid substrates.

### Electrodes

The gate electrode can be any useful conductive material such as materials providing good charge injection properties (low injection barrier). For example, the gate electrode can comprise doped silicon, or a metal, such as aluminum, chromium, gold, silver, nickel, palladium, platinum, tantalum, and titanium. Conductive polymers also can be used, for example polyaniline or poly(3,4-ethylenedioxythiophene)/poly(styrene sulfonate) (PEDOT:PSS). In addition, alloys, combinations, and multilayers of these materials can be useful. In some OTFTs, the same material can provide the gate electrode function and also provide the support function of the substrate. For example, doped silicon can function as the gate electrode and support the OTFT.

The gate electrode can be a thin metal film, a conducting polymer film, a conducting film made from conducting ink or paste, or the substrate itself can be the gate electrode, for example heavily doped silicon.

Further examples of gate electrode materials include but are not restricted to aluminum, gold, chromium, indium tin oxide, conducting polymers such as doped polyaniline, polystyrene sulfonate-doped poly(3,4-ethylenedioxythiophene) (PSS-PEDOT), conducting ink/paste comprised of carbon black/graphite or colloidal silver dispersion in polymer binders.

The gate electrode layer can be prepared by vacuum evaporation, sputtering of metals or conductive metal oxides, coating from conducting polymer solutions or conducting inks by spin coating, casting or printing. The thickness of the gate electrode layer ranges for example from about 10 to about 200 nanometers for metal films and in the range of about 1 to about 10 micrometers for polymer conductors.

The source and drain electrodes can be any useful conductive material.

They can be fabricated from materials which provide a low resistance ohmic contact to the semiconductor layer.

Typical materials suitable for use as source and drain electrodes include those of the gate electrode materials such as gold, nickel, aluminum, platinum, conducting polymers and conducting inks.

Typical thicknesses of source and drain electrodes are about, for example, from about 40 nanometers to about 10 micrometers with the more specific thickness being about 100 to about 400 nanometers

The source and drain electrodes can be produced by any useful means such as physical vapor deposition (e.g., thermal evaporation, sputtering), plating, or ink jet printing. The patterning of these electrodes can be accomplished by known methods such as shadow masking, additive photolithography, subtractive photolithography, printing, microcontact printing, transfer printing, and pattern coating.

Interfacial properties between the source/drain electrodes and the semiconductor layer may give rises to contact resistance. The contact resistance between the semiconductor and the electrodes can dominate the transport properties of the TFT devices.

The reduction of contact resistance between the electrodes and the semiconductor layer by increasing the conductivity of the semiconductor at the region which is close to the electrode (or “contact region”). This can be accomplished by doping the contact regions with appropriate dopants or dopant precursors.

Dopant or dopant precursor-stabilized metal nanoparticles such as acid-stabilized metal nanoparticles are used to deliver a dopant or chemically reacted dopant to a contact region of the semiconductor layer.

The source electrode and drain electrode are separated from the gate electrode by the gate dielectric, while the organic semiconductor layer can be over or under the source electrode and drain electrode. The source and drain electrodes can be any useful conductive material. Useful materials include most of those materials described above for the gate electrode, for example, aluminum, barium, calcium, chromium, gold, silver, nickel, palladium, platinum, titanium, polyaniline, PEDOT:PSS, other conducting polymers, alloys thereof, combinations thereof, and multilayers thereof. Some of these materials are appropriate for use with n-type semiconductor materials and others are appropriate for use with p-type semiconductor materials, as is known in the art.

The thin film electrodes (that is, the gate electrode, the source electrode, and the drain electrode) can be provided by any useful means such as physical vapor deposition (for example, thermal evaporation or sputtering) or ink jet printing or lamination. The patterning of these electrodes can be accomplished by known methods such as shadow masking, additive photolithography, subtractive photolithography, printing, microcontact printing, and pattern coating and/or laser induced thermal imaging (LITI).

### Insulating or Dielectric Layer(S)

The dielectric layer serves as the gate dielectric in a thin film-transistor. The layer should
i) be a smooth uniform layer without pinholes,
ii) have a high dielectric constant to enable the thin film transistor to operate at lower voltages
iii) have no adverse effects on the transistor's performance.

For flexible integrated circuits on plastic substrates, the dielectric layer should be prepared at temperatures that would not adversely affect the dimensional stability of the plastic substrates, i.e., generally less than about 200.degree. C., preferably less than about 150.degree. C.

The dielectric layer can be composed of organic or inorganic materials.

Inorganics: strontiates, tantalates, titanates, zirconates, aluminum oxides, silicon oxides, tantalum oxides, titanium oxides, silicon nitrides, barium titanate, barium strontium titanate, barium zirconate titanate, zinc selenide, and zinc sulphide, siloxy/metal oxide hybrids.

In addition, alloys, combinations, and multilayers of these can be used for the gate dielectric. Organics. Various homopolymers, copolymers, and functional copolymers such as polyimides, poly(vinylphenol) poly(methyl methacrylate), polyvinylalcohol, poly(perfluoroethylene-co-butenyl vinyl ether) and benzocyclobutene.

Most of the organic or polymer dielectric materials generally have low dielectric constants, and thus cannot enable low-voltage electronic devices.

However, it is desirable to provide a dielectric material composition that is solution processable and which composition can be used in fabricating the gate dielectric layers of thin film transistors.

It is also desirable to provide a material for fabricating the dielectric layer for thin film transistors that can be processed at a temperature compatible with plastic substrate materials to enable fabrication of flexible thin film transistor circuits on plastic films or sheets.

The gate dielectric is generally provided on the gate electrode. This gate dielectric electrically insulates the gate electrode from the balance of the OTFT device. Useful materials for the gate dielectric can comprise, for example, an inorganic electrically insulating material.

Specific examples of materials useful for the gate dielectric include strontiates, tantalates, titanates, zirconates, aluminum oxides, silicon oxides, tantalum oxides, titanium oxides, silicon nitrides, barium titanate, barium strontium titanate, barium zirconate titanate, zinc selenide, and zinc sulfide. In addition, alloys, combinations, and multilayers of these materials can be used for the gate dielectric. Organic polymers such as poly (arylene ethers), bisbenzocyclobutenes, fluorinated polyimides, polytetrafluoroethylene, parylenes, polyquinolines etc are also useful for the gate dielectric.

### Dielectric/Organic Semiconductor Interfaces

One area of concern in organic electronic devices is the quality of the interface formed between the organic semiconductor and another device layer.

Self-assembled monolayer (SAMs) interposed between a gate dielectric and an organic semiconductor layer have been utilised to create more compatible interfaces.

Early examples of using SAMs included using a silazane or silane coupling agents on silicon oxide surfaces. Other approaches have been to include a polymeric interlayer between the dielectric and semiconductor layers.

The present invention further provides a thin film transistor device comprising

a plurality of electrically conducting gate electrodes disposed on a substrate;

a gate insulator layer disposed on said electrically conducting gate electrodes;

an organic semiconductor layer disposed on said insulator layer substantially overlapping said gate electrodes; and

a plurality of sets of electrically conductive source and drain electrodes disposed on said organic semiconductor layer such that each of said sets is in alignment with each of said gate electrodes;

wherein said organic semiconductor layer is prepared using a pressure and optional temperature treatment as described above.

The present invention further provides a process for preparing a thin film transistor device comprising the steps of:

depositing a plurality of electrically conducting gate electrodes on a substrate;

depositing a gate insulator layer on said electrically conducting gate electrodes;

depositing a semiconducting material as described above, especially containing an organic semiconducting compound, followed by application of pressure and optionally temperature as described above, thus obtaining a semiconductor layer substantially overlapping said gate electrodes;

depositing a plurality of sets of electrically conductive source and drain electrodes on said layer such that each of said sets is in alignment with each of said gate electrodes, thereby producing the thin film transistor device.

Any suitable substrate can be used to prepare the thin films semiconducting layer of the present invention. Preferably, the substrate used to prepare the above thin films is a metal, silicon, plastic, paper, coated paper, fabric, glass or coated glass.

The gate electrode could also be a patterned metal gate electrode on a substrate or a conducting material such as, a conducting polymer, which is then coated with an insulator applied either by solution coating or by vacuum deposition on the patterned gate electrodes. The insulator can be a material, such as, an oxide, nitride, or it can be a material selected from the family of ferroelectric insulators, including but not limited to PbZrₓTi₁₋ₓO₃ (PZT), Bi₄Ti₃O₁₂, BaMgF₄, Ba(Zr₁₋ₓTiₓ)O₃ (BZT), or it can be an organic polymeric insulator.

Any suitable solvent can be used to disperse the precursor material for the semiconducting layer to be formed, provided it is inert and can be removed from the substrate by conventional drying means (e.g. application of heat, reduced pressure, airflow etc.). Suitable organic solvent for processing the semiconductors of the invention include, but are not limited to, aromatic or aliphatic hydrocarbons, halogenated such as chlorinated hydrocarbons, esters, ethers amides, such as chloroform, tetrachloroethane, tetrahydrofuran, toluene, ethyl acetate, dimethyl formamide, dichlorobenzene, propylene glycol monomethyl ether acetate (PGMEA), and especially alcohols (such as methanol, ethanol, propanol, butanol etc.), ketones (such as acetone, methyl ethyl ketone), water, and mixtures thereof. The liquid is then applied by a method, such as, spin-coating, dip-coating, screen printing, microcontact printing, doctor blading or other solution application techniques known in the art on the substrate.

The present process may be carried out using conventional devices for the application of pressure on substrate materials, especially as known in the field of printing (e.g. gravure or offset).

Examples for semiconducting materials especially useful in the present process include those based on the following compounds:

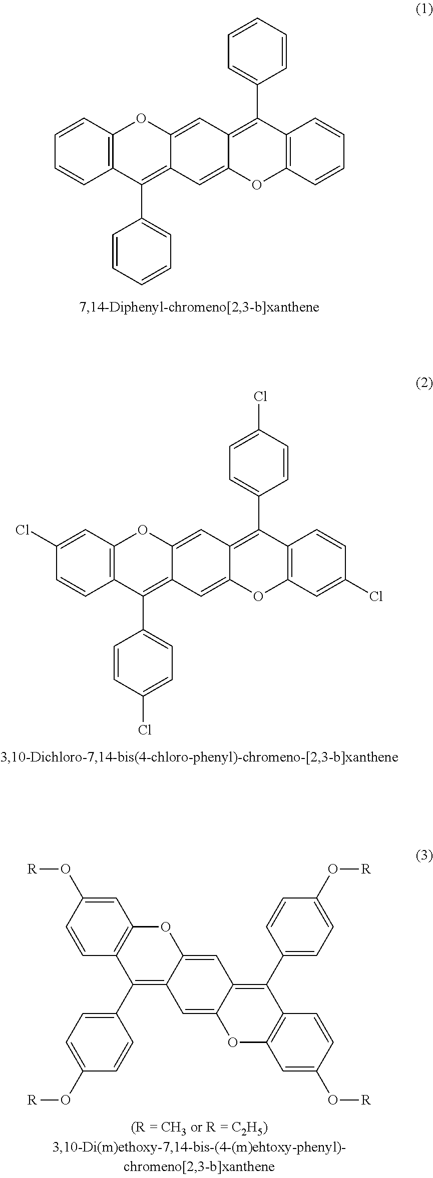

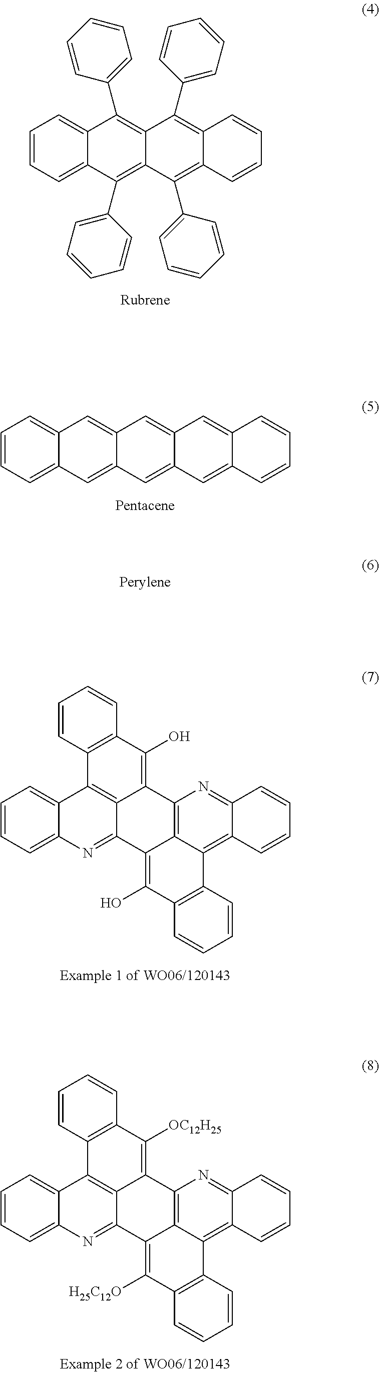

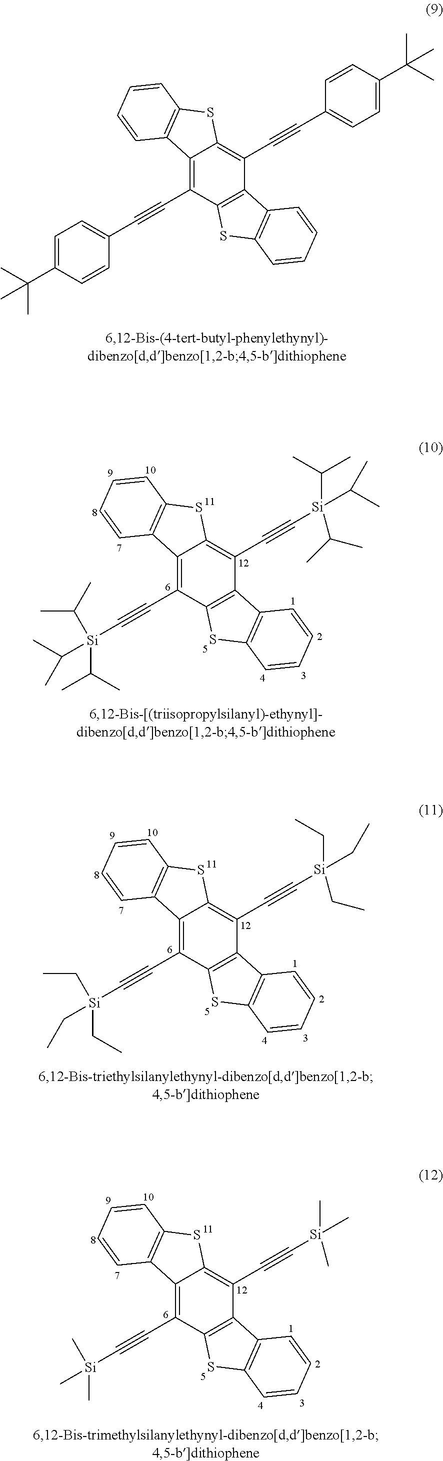

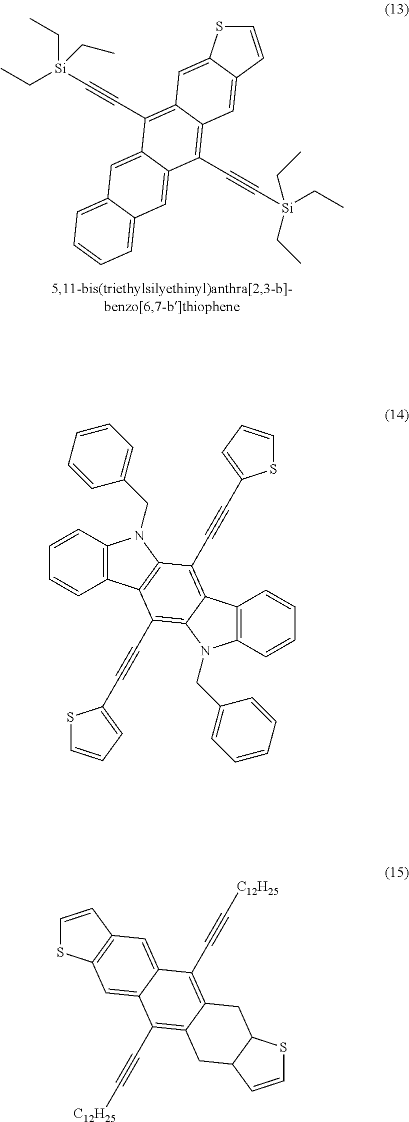

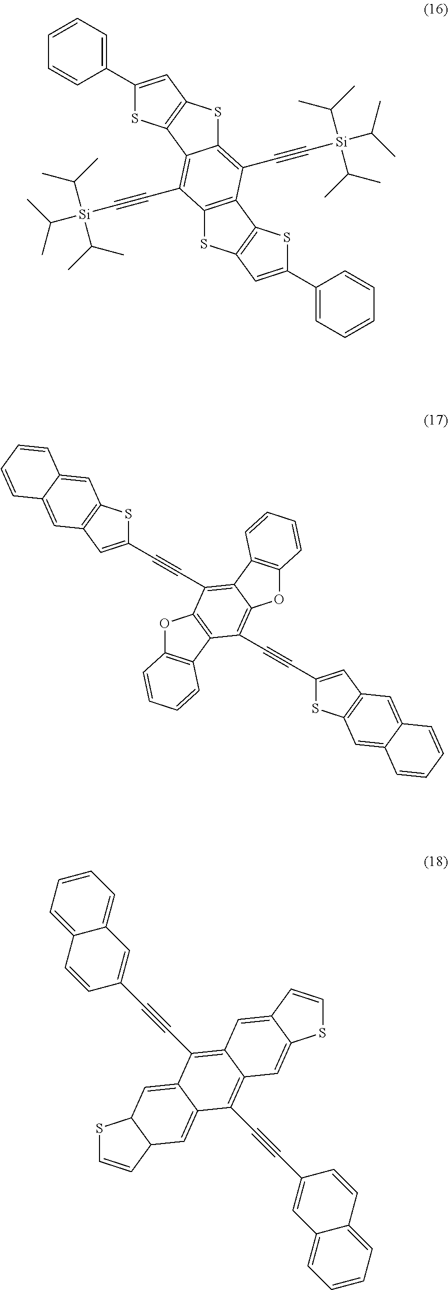

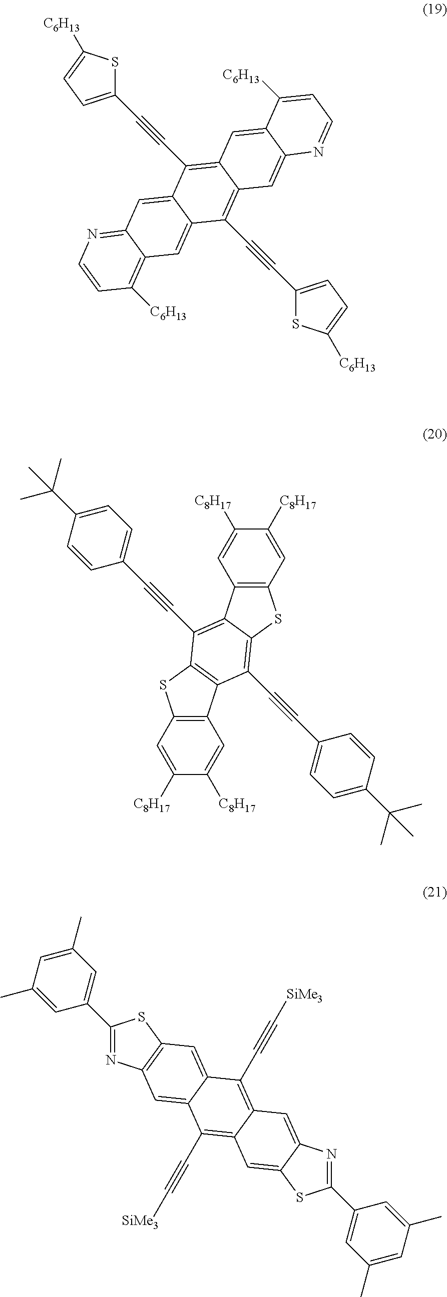

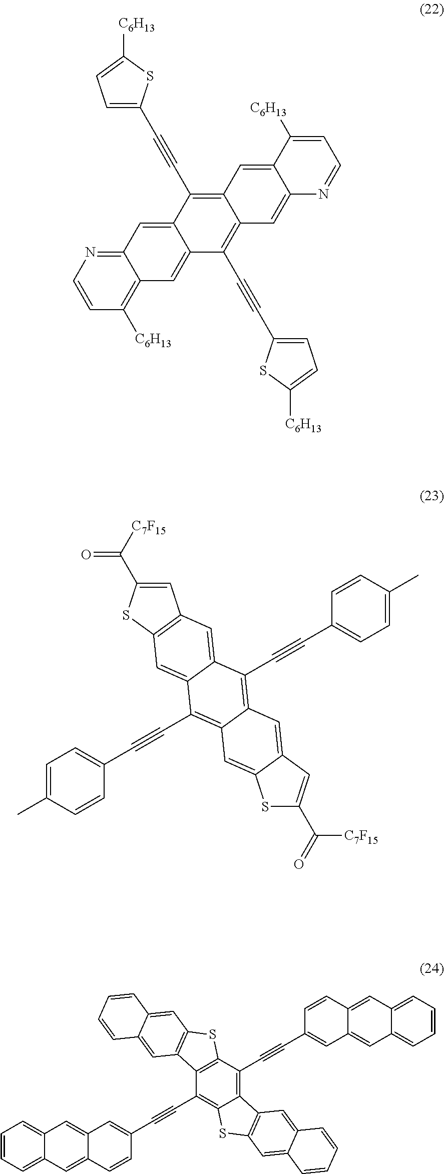

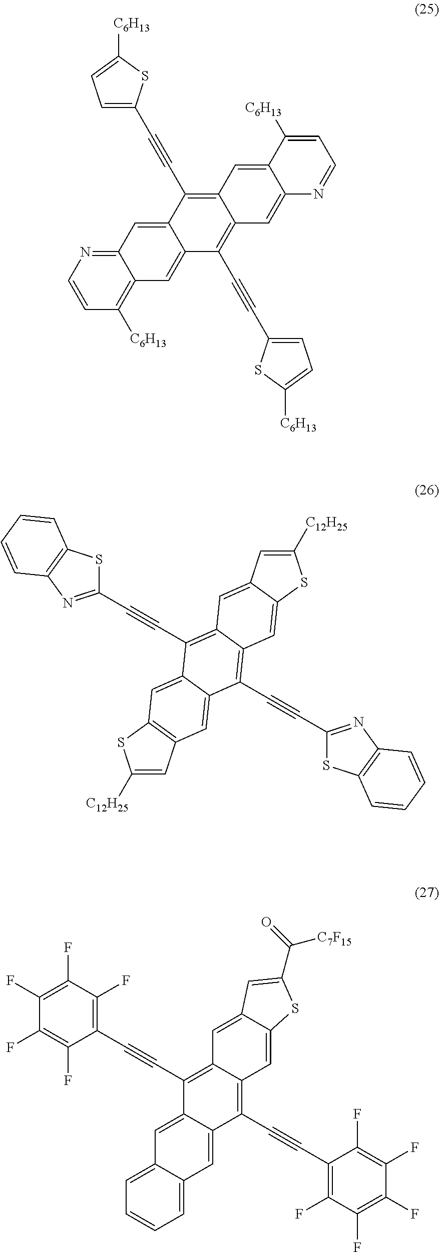

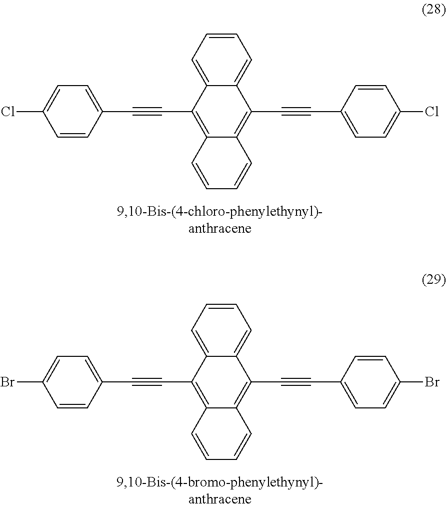

Organic thin film transistors are used to make diodes, ring oscillators, rectifiers, inverters etc for logic circuit applications. Such organic circuits can be used for high-volume microelectronics applications and throw-away products such as contactless readable identification (e.g. single-use barcodes, smart cards) and radio frequency identification tags (RFID tags).

The processing characteristics and demonstrated performance of OTFTs suggest that they can also be competitive for existing or novel thin-film-transistor applications requiring large-area coverage, structural flexibility, low-temperature processing, and, especially, low cost. Such applications include switching devices for active-matrix flat-panel displays based on liquid crystal pixels, electrophoretic particles and organic light-emitting diodes.

Thus, further subjects embraced by the present invention are an electronic device obtainable by a process according to the invention, as well as a composition or device comprising a semiconducting layer produced by a process as described above, preferably for uses such as organic transistor, photodiode, sensor, solar cell.

Commercial applications for organic semiconductor layers prepared according to the invention include driving circuits of display elements (such as electronic paper, digital paper, organic EL elements, electrophoresis type display elements or liquid crystal elements), logic circuits, memory/storage devices and memory elements used in electronic tags, smart cards, sensors, solar cells.

The following examples are for illustrative purposes only and are not to be construed to limit the instant invention in any manner whatsoever. Room temperature/ambient temperature depicts a temperature in the range 20-25° C.; over night denotes a time period in the range 12-16 hours. Percentages are by weight unless otherwise indicated.

Abbreviations used in the examples or elsewhere:

M concentration in moles per litre

n-BuLi n-butyllithium

OTS octadecyltrichlorosilane

MS mass spectrometry

μ non-contact corrected saturation field-effect mobility [cm²/Vs]

SEM scanning electron microscopy

Vₒₙ onset voltage

Vₜ threshold voltage

I_{off} off-current [A]

Iₒₙ/I_{off} on-off current ratio

### Comparison 1: Single Crystal Field-Effect Transistor

Single crystals are grown by physical vapour transport in a horizontal oven with in inert carrier gas (argon). A temperature gradient is present, resulting in evaporation of 7,14-diphenyl-chromeno[2,3-b]xanthene (1) at 295° C. and crystallisation between 270° C. and 240° C. Crystals are obtained as thin red-brown plates.

A crystal is placed on a pre-fabricated substrate, consisting of a heavily doped silicon wafer, 300 nm of thermally grown SiO₂ and 18 nm thick gold contacts deposited through a shadow mask. The SiO₂ surface is treated with octadecyltrichlorosilane (OTS) by exposing it in vacuum to OTS vapour at 120° C. for 1 hour.

The FET is characterized using an HP 4155A® semiconductor parameter analyzer by sweeping the gate voltage V_{G} and keeping the drain voltage V_{D} constant and vice versa (see FIG. 1). Both output and transfer characteristics contain only a small hysteresis.

Data for this sample are: Mobility μₛₐₜ=μₗᵢₙ=0.16 cm²/Vs, Vₜ=1 V, S=1.5 V/dec and Iₒₙ/I_{off}=10⁵.

### Comparison 2: Thin Film Obtained by Vacuum Deposition

A highly doped Si-wafer with 300 nm thermally grown SiO₂ is cut and cleaned with hot acetone and hot isopropanol. The sample is immersed in piranha-solution (30% hydrogen peroxide in 70% sulfuric acid) for 10 minutes and thoroughly washed with ultra pure water (18.2 MΩcm). Subsequently, the SiO₂ surface is treated with octadecyltrichlorosilane (OTS) by a vapour prime process. For this process, the sample and ˜0.3 ml of OTS are heated to 125° C. in a vacuum for three hours. The compound (1) is evaporated on the sample through a shadow mask in a high vacuum (base pressure 2×10⁻⁶ mbar). The substrate is kept at a temperature of 75° C. during the deposition. The deposition rate and the film thickness are measured with a water-cooled quartz crystal in the chamber. 50 nm of (1) is deposited at a rate of 0.5 Å/s. Gold contacts are vacuum-evaporated onto the formed thin-film in a separate chamber resulting in multiple thin-film transistor test structures on the sample with a channel length of 100 μm and a channel width of 500 μm.

Device characteristics are measured in a dry He atmosphere using a HP 4155A semiconductor parameter analyzer. For the transfer characteristic, the gate voltage V_{g} is swept to −60 V and back in steps of 0.5 V, while keeping the drain voltage at V_{d}=−50 V. The transfer characteristics are analyzed in terms of non-contact corrected saturation field-effect mobility, onset voltage, threshold voltage, off-current and on-off ratio. Additionally, the output characteristics of the same device are measured.

The mobility is μ=1.7×10⁻³ cm²/Vs. The onset voltage of the device is small and negative (Vₒₙ=−1.3 V) and the threshold voltage is Vₜ=−2.5 V. The off-current I_{off} is ˜1×10⁻¹¹ A and the on-off current ratio Iₒₙ/I_{off} is 1×10⁴.

### Comparison 3: Influence of the Substrate Temperature on TFT

Thin-film transistors are made from (1) as described above. The substrates are kept at various substrate temperatures during thin-film deposition. Approximately three devices are characterized on each sample.

Table 1 summarizes average transistor parameters for each sample and shows that the mobility is higher for samples kept at a lower temperature during the deposition process. Average field-effect mobilities of 1.3×10⁻² cm²/Vs are possible in thin-films of (1) deposited at T=0° C.

TABLE 1
Transistor parameters for films deposited at temperature T

| T [° C.] | μ [cm²/Vs] | V_{ON} [V] | Vₜ [V] | I_{off} [A] | Iₒₙ/I_{off} |
|---|---|---|---|---|---|
| 0 | 8.5 × 10⁻³ | −0.6 | −4.5 | 1 × 10⁻¹¹ | 5 × 10⁴ |
| 30 | 8.7 × 10⁻³ | +1.8 | −1.4 | 5 × 10⁻¹⁰ | 5 × 10³ |
| 45 | 6.4 × 10⁻³ | +2.3 | −3.2 | 5 × 10⁻¹¹ | 1 × 10⁴ |
| 75 | 2.2 × 10⁻³ | −0.2 | −1.7 | 1 × 10⁻¹¹ | 1 × 10⁴ |
| 90 | 9.5 × 10⁻⁴ | +0.9 | −0.9 | 1 × 10⁻¹¹ | 5 × 10³ |

### Comparison 4: Effect of the OTS Surface Treatment

Thin-film transistors from (1) are prepared as described above on a sample with OTS and on a reference sample. The reference sample is taken from the same wafer and is cleaned with the normal sample. After the cleaning, the reference sample is not subjected to the surface treatment with OTS. The reference sample is installed close to the sample with OTS in the deposition chamber and the compound (1) is evaporated on both samples at a fixed substrate temperature of T=0° C. in the same deposition run.

The surface treatment leads to a large gain in device quality. The table contains transistor parameters from both devices. The mobility with OTS is 1.0×10⁻² cm²/Vs and the mobility from the reference sample is 2.0×10⁻⁵ cm²/Vs (see Table 2), i.e. lower by a factor of 500.

TABLE 2
Transistor parameters after vacuum deposition

| | μ | | Vₜ | | |
|---|---|---|---|---|---|
| Sample | [cm²/Vs] | V_{ON} [V] | [V] | I_{off} [A] | Iₒₙ/I_{off} |
| with OTS | 1.0 × 10⁻² | −0.5 | −4 | <5 × 10⁻¹² | 1 × 10⁵ |
| without OTS | 2.0 × 10⁻⁵ | −12.6 | ~−12 | 1 × 10⁻¹² | 5 × 10² |
| (reference sample) | | | | | |

### EXAMPLES OF THE INVENTION

### Example 1

Organic transistors are realised by the following steps. The Quinoid Heteroacene (1) is used as channel material. The synthesized powder is ball milled in n-butanol to an average particle size smaller than 1 μm. These particles are dispersed in n-butanol in a concentration of 2% (by weight). Transistor substrate is an n-doped Silicon wafer with a specific resistivity of 5 Ωcm. A 100 nm thermal SiO₂ oxide serves as gate insulator of 32.6 nF/cm² capacitance. A 100 nm thick Gold layer is evaporated on top of the SiO₂ surface and patterned into inter-digitated arrays of source-drain contacts. The adhesion of the Gold layer on top of the SiO₂ layer is enhanced by a thermally evaporated 10 nm thick Titanium adhesion layer. The channel width—as defined by the source-drain electrodes—is 1 cm. The channel length is set to 4, 8, 15, or 30 μm. The carefully cleaned SiO₂ surface is derivatized with ocyltrichlorosilane OTS (Alrich), which is known to improve transistor performance. On top of the transistor substrate an approximately 2.5 μm thick layer of the dispersion of (1) is deposited in air by drop-casting. For this 100 μl of the dispersion is distributed on the substrate with a pipette and left to dry in lab atmosphere. To bring the layer into a crystalline phase with enhanced charge carrier mobility, the dried layer is hot pressed in a Graseby Specac press (T-40 Autopress). For this a cover glass slide is placed on top of the coated transistor substrate as indicated in FIG. 1. The slide is sputter coated with an approximately 10 nm thick Teflon release coating. First the desired pressure is applied by lowering the upper punch of the press. Then both upper and lower punch are heated to the desired temperature and then held at this temperature for 30 minutes. Next, the heater of the punches is switched off and the system left to cool. Once the temperature drops to 80° C., the pressure is relieved. The ramp up and down of the pressure and the temperature are schematically shown in FIG. 1.

A further layer is produced in the same way, but using a Perfluoro-silane coating on the slide.

Test series exploring the temperature range from 25° C. up to 250° C. and the pressure range from 60 bar up to 500 bar are performed. FIG. 3 shows an example of a transfer characteristic (drain current over gate voltage) for a transistor of 30 μm channel length pressed at 250 bar and 180° C. for 30 min. All measurements are performed under N₂ atmosphere. The field-effect mobility is deduced from the slope of the square-root of the drain current. The field-effect mobility of this transistor is 4.7 10⁻³ cm²/Vs. The corresponding output characteristic is shown in FIG. 4. The influence of the process temperature on the charge carrier mobility is depicted in FIG. 5. All samples of this series are pressed at 250 bar, except the room-temperature sample. The latter is obtained for a pristine layer of (1) (no pressure step) and serves as reference. As can be seen, a dramatic increase in field-effect mobility occurs between a temperature of 120° C. and 160° C. Above 200° C. a decrease is observed. Thus, at 250 bar the press temperature for optimal field-effect mobility is around 160° C.

The optical appearance of the samples pressed at this temperature is significantly different from the untreated layer. The influence of the pressure is shown in FIGS. 6 and 7. All samples of this series are pressed at a temperature of 160° C. except for 1 sample which is processed under 250 bar at 40° C. A peak in the mobility vs. pressure curve occurs at about 250 bar. Below this pressure the mobility decreases rapidly. Heat treatment at 160° C. shows a distinct improvement in the homogenity of the layer over the sample treated at 40° C.

The mobility achieved with this process is 0.01 cm²/Vs at present, which is only a factor of 20 lower than value measured on (1) single-crystalline (and thus perfectly ordered) field-effect transistors.

### BRIEF DESCRIPTION OF FIGURES

FIG. 1 shows the arrangement of the semiconductor material between cover glass slide and coated transistor substrate before pressing (top) and a schematic picture of the pressure and temperature treatment.

FIG. 2 shows typical designs of organic transistors.

FIG. 3 shows an example of a transfer characteristic (drain current over gate voltage) for a transistor of 30 μm channel length pressed at 250 bar and 180° C. for 30 min.

FIG. 4 shows the corresponding output characteristics.

FIG. 5 shows the influence of the process temperature on the charge carrier mobility.

FIG. 6 shows the influence of the process pressure on the charge carrier mobility.

FIG. 7 shows a SEM cross section through a layer of semiconductor particles as of FIG. 6 (pressure treatment at 160° C.; right: 62.5 bar; left: 375 bar).

FIG. 8 gives a schematic view of an organic Schottky diode (Substrate=12; Ohm Contact=14; Doped buffer layer=16; Organic semiconductor layer=18; Schottky contact=20).

FIG. 9 gives a schematic view of an organic solar cell (OS=organic semiconductor).

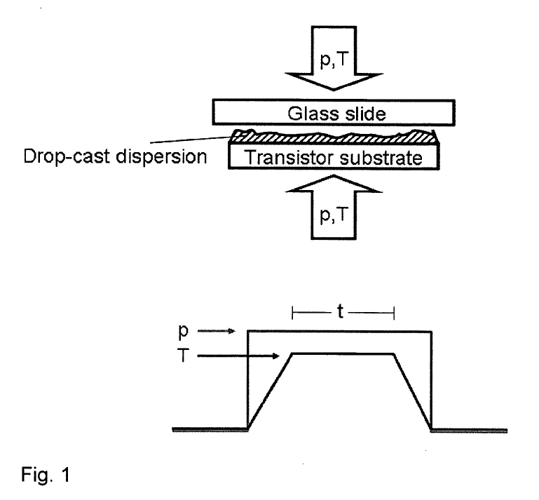

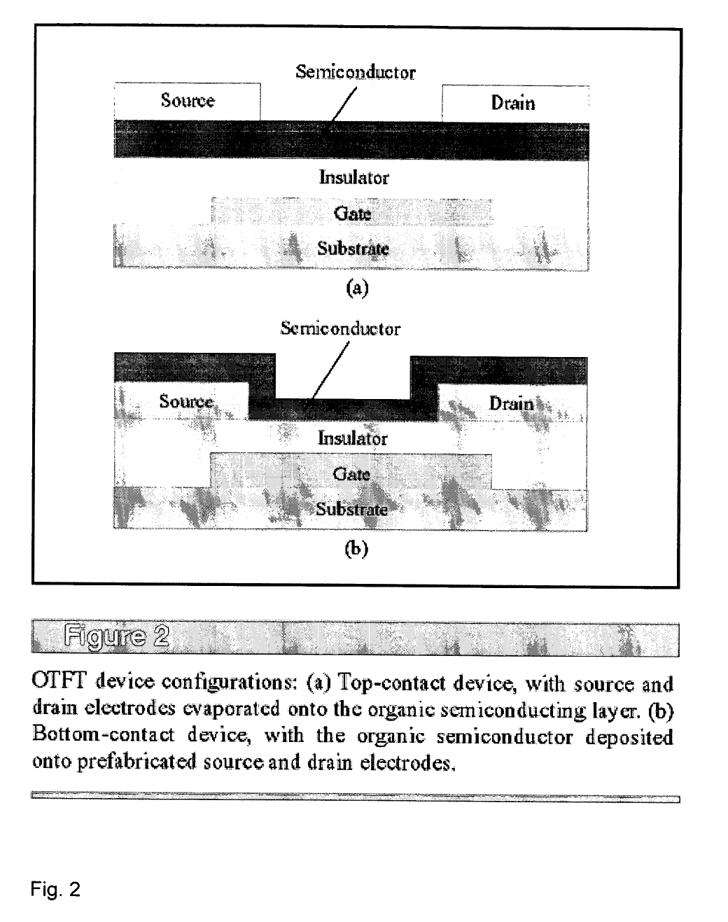

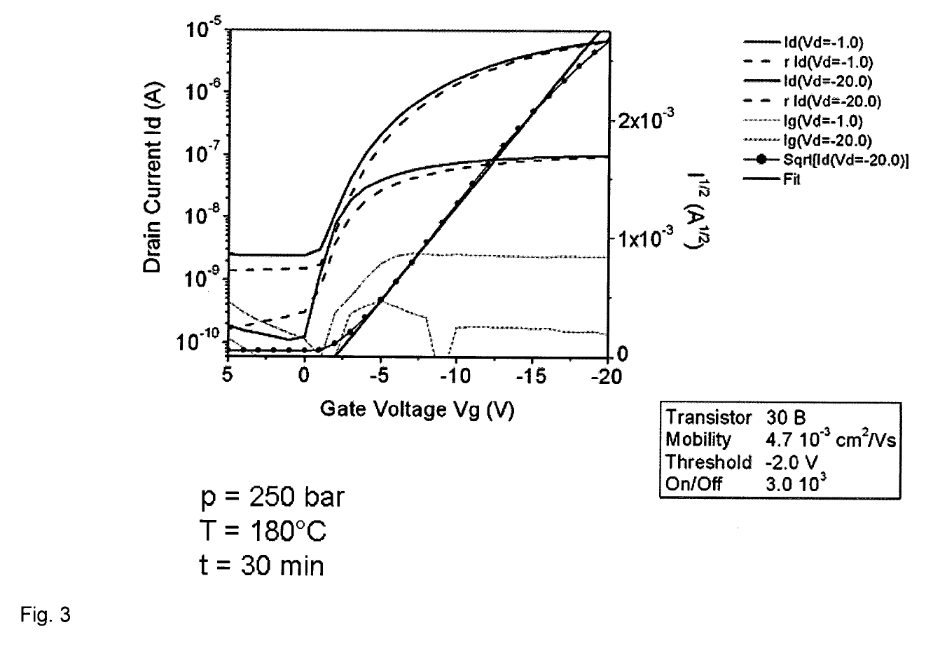

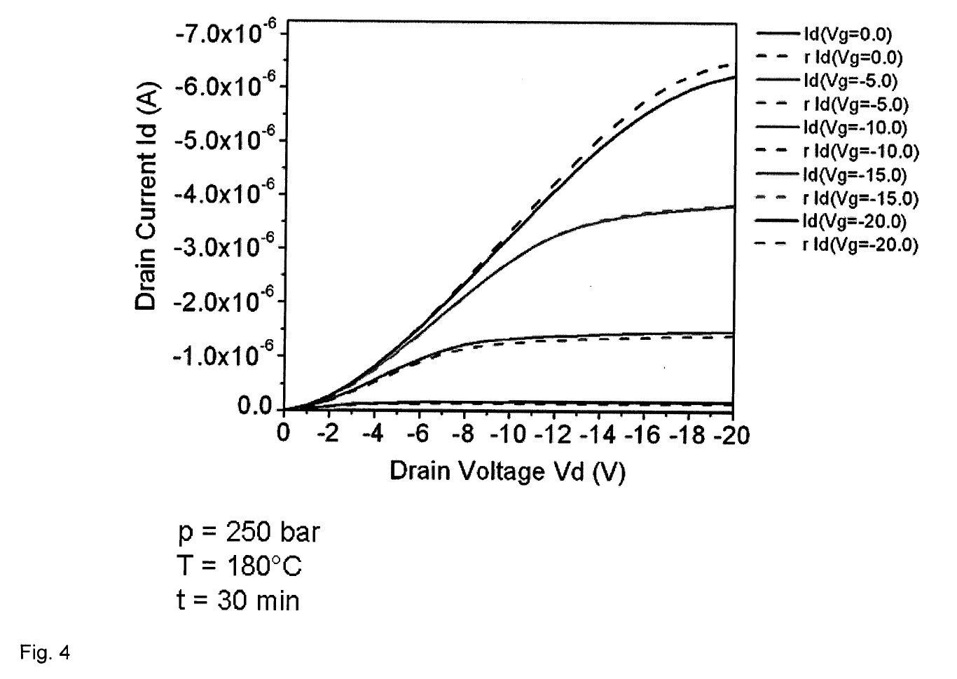

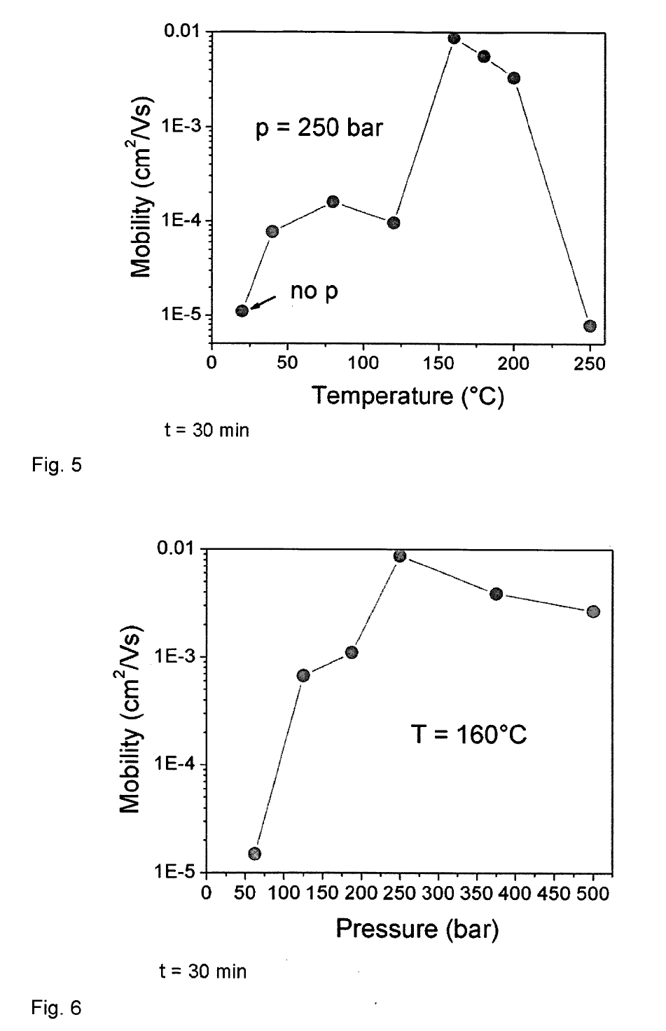

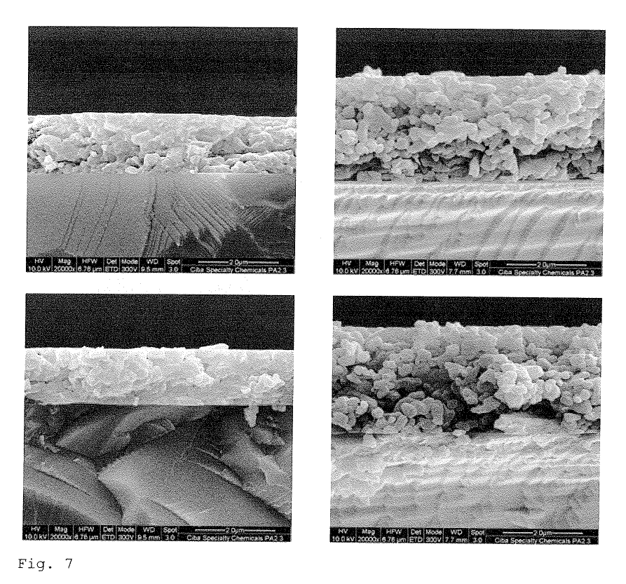

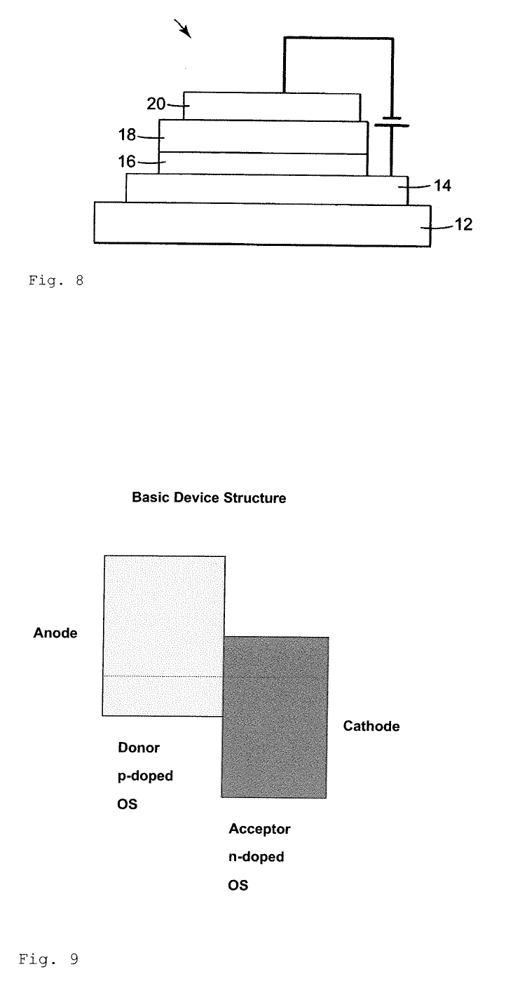

1. A process for the preparation of an electronic device, which process comprises application or deposition of particles of a semiconducting material consisting essentially of an organic semiconductor on a suitable surface, and converting these particles into a semiconducting layer on a substrate by application of pressure and optionally elevated temperatures.

2. A process for the preparation of an electronic device, which process comprises the formation of a semiconducting layer on a substrate by application of a semiconducting material consisting essentially of an organic semiconductor on a suitable surface, and subjecting the semiconducting material to dynamic or directional pressure in the range 12000 to 100000 kPa, and optionally to elevated temperatures.

3. A process according to claim 1 wherein the semiconducting material comprises one or more organic semiconducting compounds optionally mixed with one or more other components selected from dispersants, high melting crystal growth promoters, plasticizers, mobility enhancers, dewetting agents, dopants, binders.

4. A process according to claim 1 in which the organic semiconductor(s) is initially subjected to pressure and later subjected to elevated temperatures with or without the high pressure being maintained.

5. A process according to claim 1 in which the organic semiconductor(s) is subjected to high pressure and elevated temperature simultaneously, and/or wherein elevated temperature is applied prior to the high pressure treatment.

6. A process according to claim 1 wherein the organic semiconductor(s) is held at an annealing temperature ranging from 40 to 250° C., for a period of time after its initial submission to high pressure and elevated temperature.

7. A process according to claim 1 wherein the semiconducting material is in the form of a powder and/or pellets before being subjected to high pressure and/or elevated temperature.

8. A process according to claim 1 wherein the elevated temperature is in the range from 40 to 250° C., and the time for the application of pressure is 0.01 to 3000 s.

9. A process according to claim 1 in which a single organic semiconductor compound is used, which makes up at least 90% by weight of the particle material.

10. A process according to claim 1 wherein the organic semiconductor used is a low molecular weight compound of 180-2000 g/mol and/or a polymer from the molecular weight range 1000-300000 g/mol.

11. A process according to claim 1 wherein the semiconducting material is applied as a powder or a particle dispersion in a volatile liquid, especially an organic liquid boiling at normal pressure within the range 30-200° C. or water or mixtures of the organic liquid with water, wherein the average particle size of the semiconducting material is within the range 5-5000 nm.

12. A process according to claim 11 wherein the dispersion liquid comprises a further component in dispersed or dissolved form.

13. A composition or device comprising a semiconducting layer produced by a process as described in claim 1, which device is an organic transistor, photodiode, sensor or solar cell.

14. Electronic device obtained by a process according to claim 1, which device is an organic transistor, photodiode, sensor or solar cell.

15. A method of forming a film on a substrate comprising the steps of applying an organic semiconducting solid particle material consisting essentially of an organic semiconductor, on a substrate by application of pressure and optionally elevated temperatures.
